(19) United States
(12) Patent Application Publication
(10) Pub. No.: US 2015/0097259 A1
(43) Pub. Date: Apr. 9, 2015

(54) CONDUCTIVE VIA STRUCTURE, PACKAGE STRUCTURE, AND PACKAGE OF PHOTOSENSITIVE DEVICE

(71) Applicant: Industrial Technology Research Institute, Chutung (TW)

(72) Inventors: Hsiang-Hung CHANG, Zhudong Township (TW); Wen-Chih CHEN, Zhubei City (TW); Chia-Wei JUI, Yangmei City (TW); Zhi-Cheng HSIAO, Sinpu Township (TW); Cheng-Ta KO, Taipei City (TW); Rong-Shen LEE, Zhubei City (TW); Sheng-Shu YANG, Hsinchu City (TW)

(73) Assignee: Industrial Technology Research Institute, Chutung (TW)

(21) Appl. No.: 14/570,854

(22) Filed: Dec. 15, 2014

Related U.S. Application Data
(63) Continuation-in-part of application No. 13/943,810, filed on Jul. 17, 2013.
(60) Provisional application No. 61/924,237, filed on Jan. 7, 2014.

(30) Foreign Application Priority Data
Apr. 1, 2013 (TW) 102111720
Sep. 10, 2014 (TW) 103131187

(51) Int. Cl. H01L 31/02; H01L 23/00; H01L 23/48

(52) U.S. Cl. CPC H01L 31/02002; H01L 23/481; H01L 24/09; H01L 2224/05009
USPC 257/443; 257/774

(57) ABSTRACT

Conductive plug structures suitable for stacked semiconductor device package is provided, wherein large contact region between the conductive plug structures and the corresponding pads of devices can be achieved, to reduce electrical impedance. Therefore, package structures such as photosensitive device packages using the conductive plug structures have superior electrical performance and reliability.

### CROSS-REFERENCE TO RELATED APPLICATIONS

This application is a Continuation-in-Part of co-pending application Ser. No. 13/943,810, filed on Jul. 17, 2013, which claims priority under 35 U.S.C. §119(a) to Application No. 102111720, filed in Taiwan on Apr. 1, 2013. This application also claims priority under 35 U.S.C. §119(e) to U.S. Provisional Application No. 61/924,237, filed on Jan. 7, 2014, and claims priority under 35 U.S.C. §119(a) to Application No. 103131187, filed in Taiwan on Sep. 10, 2014. The entire contents of each of the above applications are hereby incorporated by reference.

### BACKGROUND OF THE INVENTION

1. Field of the Invention

The present invention relates to conductive plug structures, and more particularly, to conductive plug structures applied in stacked semiconductor device packaging.

2. Background of the Invention

By stacking a plurality of semiconductor devices in a vertical way (Z-axis), stacked semiconductor device packaging could increase the package density and reduce the width and length (X, Y axis) of the package. Moreover, signals travel faster between the stacked semiconductor devices because of the short distance between the stacked semiconductor devices.

In demands of microminiaturization, the stacked semiconductor packaging has been applied to most electronic devices recently. For example, control circuits and other circuits with different functions can be integrated in a single packaging structure of a light sensor device to minimize the package size, enhance the performance, and reduce the power consumption.

In stacked semiconductor device packaging, conductive plug structures are frequently applied as connections between semiconductor devices. Therefore, conductive plug structures play an important role in performance enhancement, structure reliability, and device compatibility in semiconductor device packages.

### SUMMARY OF THE INVENTION

The present invention is directed to a conductive plug structure applied in semiconductor devices.

In one aspect of the present invention, a conductive plug structure is disposed in a first device and a second device stacked below the first device, the conductive plug structure comprising a first conductive pad disposed in the first device, the first conductive pad has an opening; a first conductive pillar disposed above the first conductive pad, wherein a bottom end of the first conductive pillar is in contact with the first conductive pad and fully covers the opening; a second conductive pad disposed at the second device; and a second conductive pillar disposed between the first conductive pad and the second conductive pad, the second conductive pillar contacting and extending from the bottom end of the first conductive pillar, passing through the opening, and contacting the second conductive pad.

In another aspect of the present invention, a conductive plug structure is disposed in the first device and a second device stacked below the first device, the conductive plug structure comprising a first conductive pad disposed in the first device; a second conductive pad disposed in the second device; a first conductive link disposed at the first device; a second conductive link disposed at the second device; a first conductive pillar passing through the first device and the second device; a second conductive pillar extending from the first conductive pad and the first conductive link, wherein the second conductive pillar is in contact with the first conductive pad and the first conductive link; and a third conductive pillar extending from the second conductive pad and the second conductive link, wherein the third conductive pillar is in contact with the second conductive pad and the second conductive link.

In still another aspect of the present invention, a conductive plug structure is disposed in a first device and a second device stacked below the first device, the conductive plug structure comprising a first conductive pad disposed at the first device; a second conductive pad disposed in the second device; a first conductive pillar extending from the first conductive pad to a bottom surface of the second device; a second conductive pillar extending from the second conductive pad to the bottom surface of the second device; and a conductive link disposed on the bottom surface of the second device, wherein the conductive link is in contact with the first conductive pillar and the second conductive pillar.

In still another aspect of the present invention, a package structure of a light sensor device, comprising a carrier has a first surface, wherein a first conductive pad with an opening is disposed at the carrier; a light sensor device disposed on the first surface, the light sensor device being electrically connected to the carrier, the light sensor device comprising: a sensor array; a patterned conductive layer disposed between the sensor array and the carrier; a second conductive pad; and a conductive plug structure disposed in the carrier and the light sensor, the conductive plug structure comprising: a first conductive pillar disposed below the first conductive pad, wherein a top end of the first conductive pillar is in contact with the first conductive pad and fully covers the opening; and a second conductive pillar disposed between the first conductive pad and the second conductive pad, the second conductive pillar contacting and extending from the top end of the first conductive pillar, passing through the opening, and contacting the second conductive pad.

In still another aspect of the present invention, a package structure of a light sensor device, comprising a carrier has a first surface, wherein a first conductive pad with an opening is disposed at the carrier; a light sensor device disposed on the first surface, the light sensor being electrically connected to the carrier, the light sensor device comprising: a sensor array; a patterned conductive layer disposed between the sensor array and the carrier; a second conductive pad; and a conductive plug structure disposed in the carrier and the light sensor, the conductive plug structure comprising: a first conductive pillar contacting and extending from the first conductive pad to a bottom surface of the carrier; a second conductive pillar contacting and extending from the second conductive pad to the bottom surface of the carrier; and a patterned conductive layer disposed on the bottom surface of the carrier, wherein the patterned conductive layer is in contact with the first conductive pillar and the second conductive pillar.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 shows a conductive plug structure in accordance with one embodiment of the present invention.

FIG 2 shows a 3-D view of the conductive plug structure in FIG. 1.

FIGS. 3A to 3C illustrate a flow chart of the manufacturing process of the conductive plug structure in FIG. 1.

FIG. 4A shows a cross-sectional view of a conductive plug structure in accordance with another embodiment of the present invention.

FIG. 4B shows a cross-sectional view of a conductive plug structure in accordance with still another embodiment of the present invention.

FIGS. 5A and 5B respectively show a cross-sectional view of conductive plug structures in FIGS. 4A and 4B with an external conductive link disposed thereon.

FIG. 8 illustrates a flow chart of another method for measuring the distance from the reference point to the object.

FIGS. 6A to 6G illustrate a manufacturing process of the conductive plug structure in FIG. 5B.

FIG. 7 shows a cross-sectional view of a conductive plug structure in accordance with still another embodiment of the present invention

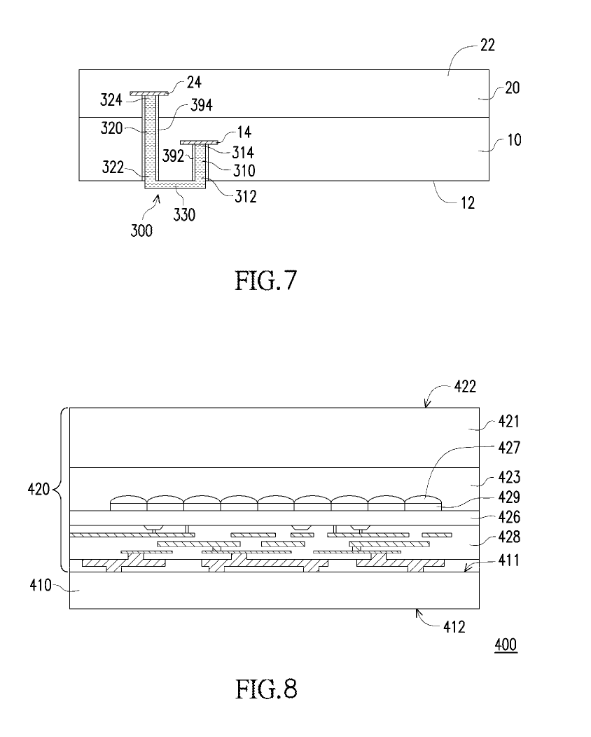

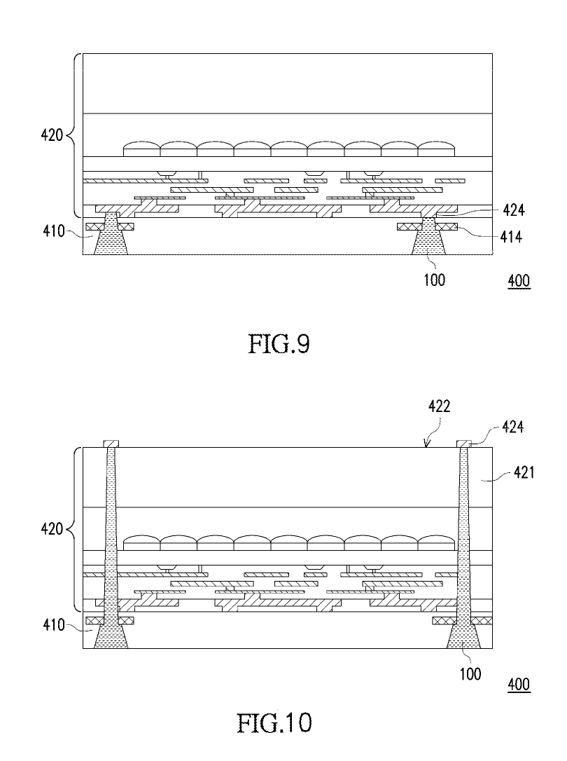

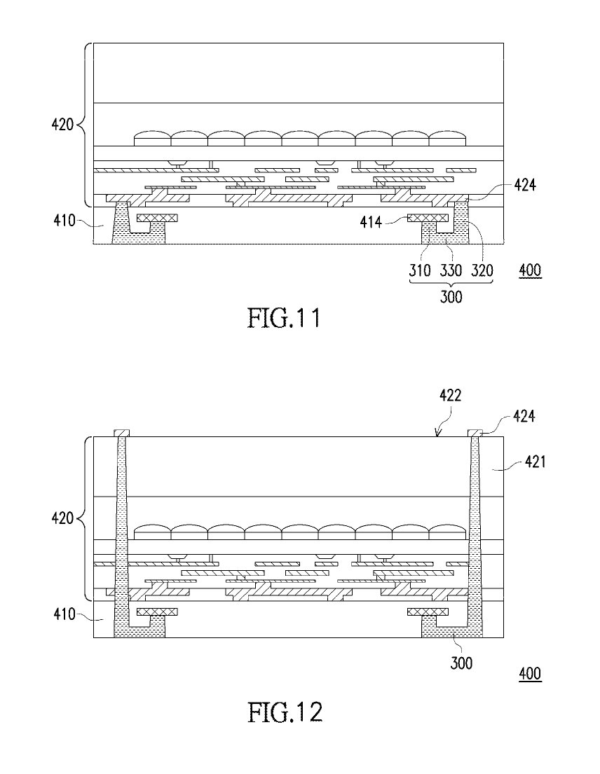

FIG. 8 shows a cross-sectional view of a light sensor device in accordance with one embodiment of the present invention.

FIG. 9 shows a cross-sectional view of a conductive plug structure in the light sensor device in FIG. 8.

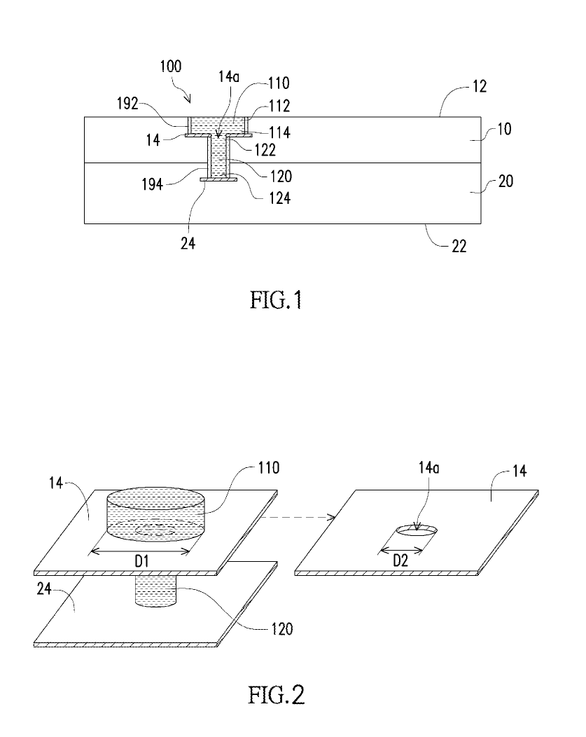

FIG. 10 shows a cross-sectional view of the conductive plug structure of FIG. 1 in a light sensor device in accordance with one embodiment of the present invention.

FIG. 11 shows a cross-sectional view of the conductive plug structure of FIG. 7 in a light sensor device in accordance with one embodiment of the present invention.

FIG. 12 shows a cross-sectional view of the conductive plug structure of FIG. 7 in a light sensor device in accordance with another embodiment of the present invention.

### DETAILED DESCRIPTION OF ILLUSTRATED EMBODIMENTS

The present invention will now be described in detail with reference to the accompanying drawings, wherein the same reference numerals will be used to identify the same or similar elements throughout the several views. It should be noted that the drawings should be viewed in the direction of orientation of the reference numerals.

FIG. 1 shows a conductive plug structure in accordance with one embodiment of the present invention. FIG. 2 shows a 3-D view of the conductive plug structure in FIG. 1.

The conductive plug structure 100 in semiconductor device package of the embodiment connects to a first device 10 and a second device 20. Each of the first device 10 and the second device 20 may be light sensor, control circuit, or any other semiconductor device. The first device 10 and the second device 20 may also be wafers or chips. In the other word, the conductive plug structure 100 could be applied to a wafer to wafer package or a chip scale package.

In the illustrated embodiment, the first device 10 and the second device 20 are stacked in a vertical way, and the first device 10 has a first surface 12 exposed. The second device 20 has a second surface 22 exposed. A conductive plug structure 100 is disposed in the first device 10 and the second device 20.

The conductive plug structure 100 comprises a first conductive pillar 110, a second conductive pillar 120, a first conductive pad 14 with an opening 14a, and a second conductive pad 24. The first conductive pad 14 and the second conductive pad 24 are respectively located in the first device 10 and the second device 20. The first conductive pillar 110 is disposed between the first surface 12 and the first conductive pad 14. The first conductive pillar 110 covers the opening 14a. A first end 112 of the first conductive pillar 110 exposed on the first surface 12, and a second end 114 of the first conductive pillar 110 is in contact with the first conductive pad 14. The second conductive pillar 120 is disposed between the first conductive pad 14 and the second conductive pad 24. A first end 122 of the second conductive pillar 120 passes through the opening 14a and is in contact with the first conductive pillar 110. A second end 124 of the second conductive pillar 120 is in contact with the second conductive pad 24.

It should be noted that the second conductive pillar 120 is not only in contact with the first conductive pillar 110 but also in contact with the inner sidewall of the opening 14a. A large contact region is between the first conductive pillar 110, the second conductive pillar 120, and the first conductive pad 14a. As a result, the conductive plug structure 100 in the illustrated embodiment provides lower electrical resistance and enhances the reliability.

In another embodiment, to avoid the electrical connection between the first conductive pillar 110 and the first device 10, a first insulation layer 192 is further disposed between the sidewall of the first conductive pillar 110 and the first device 10. Also, a second insulation layer 194 is further disposed between the sidewall of the second conductive pillar 120 and the first device 20.

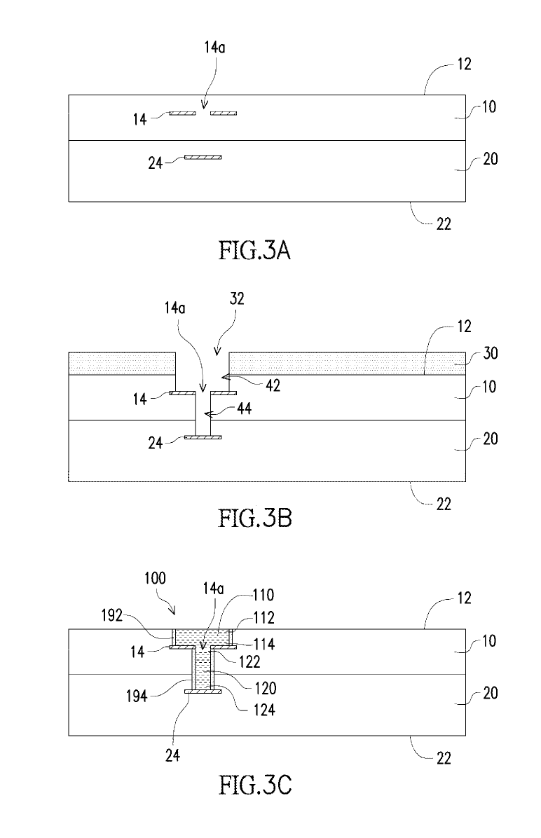

FIGS. 3A to 3C illustrate a flow chart of the manufacturing process of the conductive plug structure in FIG. 1. Firstly, the first device 10 and the second device 20 stacked on the first device 10 is provided. The first conductive pad 14 with the opening 14a is located in the first device, and the second conductive pad 24 is located in the second device. The second conductive pad 24 is located above the first conductive pad 14.

Secondly, a patterned photoresist layer 30 is formed on the first surface 12 as shown in FIG. 3B. The patterned photoresist layer 30 has a photoresist opening 32 to expose the opening 14a, wherein the photoresist opening 32 is larger than the opening 14a. Then, an etching process is followed to remove part of the first device 10 and the second device 20 exposed by the photoresist opening 32 and opening 14a. Because the material of the first conductive pad 14 and the second conductive pad 24 has a high etch selectivity to the material of the first device 10 and the second device 20, the first conductive pad 14 and the second conductive pad 24 work as an etching stopper in the etching process. A first opening 42 is formed above the first conductive pad 14, which corresponds to the photoresist opening 32. A second opening 44 is formed between the first conductive pad 14 and the second conductive pad 24, which corresponds to the opening 14a. After the etching process, the patterned photoresist layer 30 is removed.

Then, as shown in FIG. 3C, a first insulation layer 192 and a second insulation layer 194 are respectively formed on the sidewall of the first opening 42 and the second opening 44. Finally, a conductive pillar 110 and a conductive pillar 120 are formed by an electroplating process. After that, a chemical mechanical planarization process can be optionally implemented to the first device 10 and the second device 20.

The manufacturing process of the conductive plug structure 100 of the embodiment needs only one etching process to form the first opening 42 and the second opening 44. In addition, the first conductive pillar 110 and the second conductive pillar 120 of the conductive plug structure 100 have different sizes, which enhances performance and reliability with high process efficiency and low cost.

Although the above embodiments disclose a conductive plug structure in a stacked structure of two devices, it is clear that various modifications and variations can be made to the disclosed embodiments. For example, the conductive plug structure can also be implemented in a stacked structure of three or more devices. In addition, the location of the conductive pads is not limited in the devices. In an embodiment, the second conductive pad 24 may be disposed on the second surface 22 of the second device 20 as an external electrical connection. In a similar way, the first end 112 of the first conductive pillar 110 may also work as an external electrical connection.

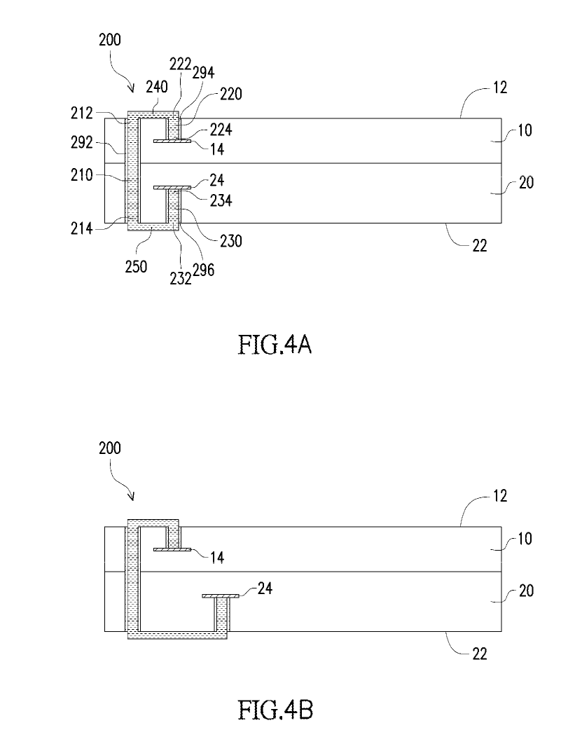

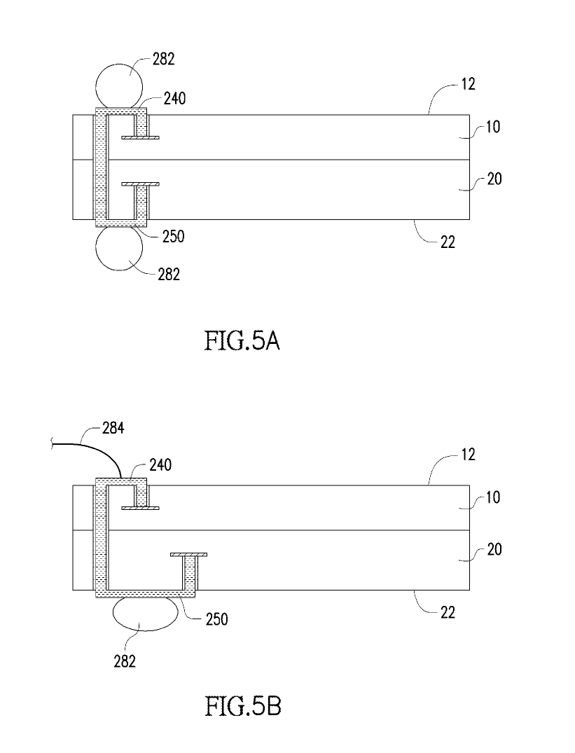

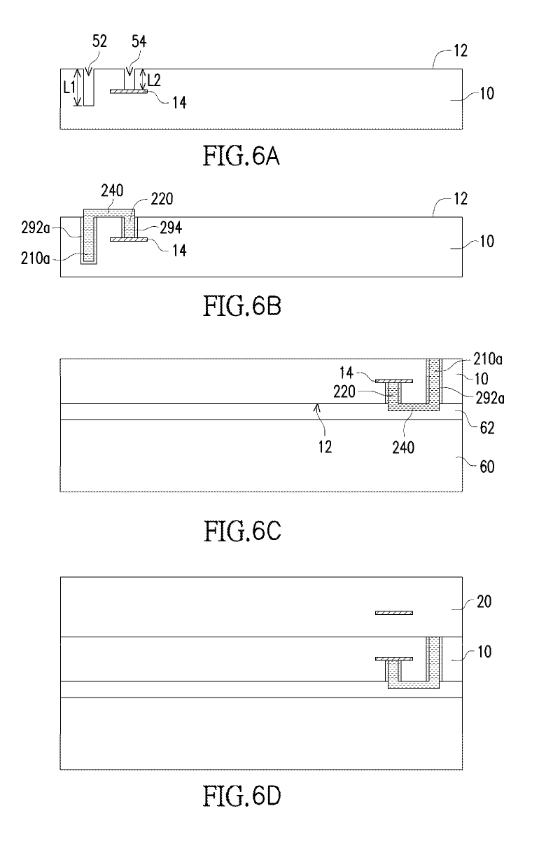

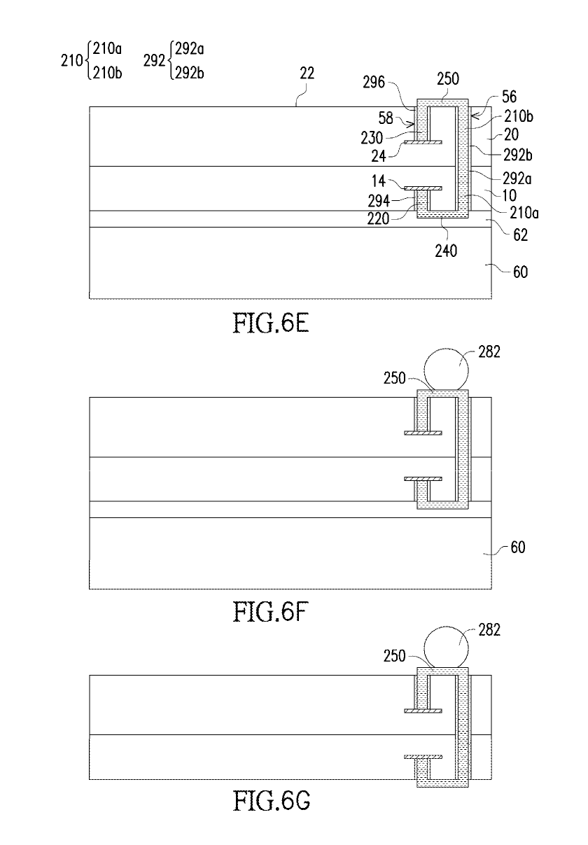

FIG. 4A shows a cross-sectional view of a conductive plug structure in accordance with another embodiment of the present invention. In this illustrated embodiment, a conductive plug structure 200 is connected to a first device 10 and a second device 20 stacked on the first device 10 in a semiconductor device package. The first device 10 and the second device 20 may be light sensor(s), control circuit(s), any other semiconductor device, wafer(s) or chip(s). In the other word, the conductive plug structure 200 could be applied to a wafer to wafer package or a chip scale package.

In this embodiment, the first device 10 and the second device 20 are stacked in a vertical way, and the first device 10 has a first surface 12 exposed. The second device 20 has a second surface 22 exposed. A conductive plug structure 100 is disposed in the first device 10 and the second device 20.

The conductive plug structure 200 comprises a first conductive pillar 210, a second conductive pillar 220, a third conductive pillar 230, a first conductive link 240, a second conductive link 250, a first conductive pad 14 with an opening 14a, and a second conductive pad 24. The first conductive pad 14 and the second conductive pad 24 are respectively located in the first device 10 and the second device 20. The first conductive pillar 210 passes through the first device 10 and the second device 20, a first end 212 of the first conductive pillar 210 is exposed on the first surface 12, and a second end 214 of the first conductive pillar 210 is exposed on the second surface 22. The second conductive pillar 220 is disposed between the first surface 12 and the first conductive pad 14, a first end 222 of the second conductive pillar 220 is exposed on the first surface 12, and a second end 224 of the conductive pillar 220 is in contact with the first conductive pad 14. The third conductive pillar 230 is disposed between the second surface 22 and the second conductive pad 24, a first end 232 of the third conductive pillar 230 is exposed on the second surface 22, and a second end 234 of the third conductive pillar 230 is in contact with the second conductive pad 24. The first conductive link 240, for example, is disposed on or above a top surface of the first device 10, extends between the first conductive pillar 210 and the second conductive pillar 220, and is in contact with the first conductive pillar 210 and the second conductive pillar 220. The second conductive link 250, for example, is disposed on or below the bottom surface of the first device 10, extends between the first conductive pillar 210 and the third conductive pillar 230, and is in contact with the first conductive pillar 210 and the third conductive pillar 230. In one embodiment, the first conductive link 240 and the second conductive link 250, for example, are redistribution layers respectively disposed on the first surface 12 and the second surface 22. The first conductive link 240 is in contact with the first end 212 of the first conductive pillar 210 and the first end 222 of the second conductive pillar 220. The second conductive link 250 is in contact with the second end 214 of the first conductive pillar 210 and the first end 232 of the third conductive pillar 230. As a result, the first conductive pad 14 and the second conductive pad 24 are electrically connected.

In another embodiment, to avoid the electrical connection between the first conductive pillar 210 and the first device 10, a first insulation layer 292 is further disposed between the sidewall of the first conductive pillar 110 and the first device 10 and the second device 20. Also, a second insulation layer 294 is further disposed between the sidewall of the second conductive pillar 220 and the first device 10, a third insulation layer 296 is further disposed between the sidewall of the third conductive pillar 230 and the second device 20.

In addition, the locations of the first conductive pad 14 and the second conductive pad 24 can be varied. In the embodiment shown in FIG. 4A, the first conductive pad 14 is aligned with the second conductive pad 24 in a vertical way. In another embodiment shown in FIG. 4B, the first conductive pad 14 is misaligned with the second conductive pad 24, but the first conductive pad 14 and the second conductive pad 24 are still electrically connected.

Although the above embodiments disclose a conductive plug structure in a stacked structure of two devices, it is clear that various modifications and variations can be made to the disclosed embodiments. In an embodiment, the conductive plug structure can also be implemented in a stacked structure of three or more devices to connect two conductive pads.

FIGS. 5A and 5B respectively show a cross-sectional view of a conductive plug structures in FIGS. 4A and 4B with an external conductive link disposed thereon. Bump 282, 284 are respectively disposed on the first conductive link 240 and the second conductive link 250 to serve as an external electrical connection.

FIGS. 6A to 6G illustrate a manufacturing process of the conductive plug structure in FIG. 5B. As shown in FIG. 6A, a first device 10 is provided. Then a first opening 52 and a second opening 54 exposing a first conductive pad 14 are formed by an etching process. The depth L1 of the first opening 52 is larger than the depth L2 of the second opening 54. Before the etching process, a patterned photoresist layer may be formed to serve as an etching mask, similar to the former embodiment. The first conductive pad 14 serves as an etching stopper, because the material of the first conductive pad 14 has high etch selectivity to the material of the first device 10.

After that, respectively forming a first part 292a of a first insulation layer 292 and a second insulation layer 294 on sidewalls of the first opening 52 and the second opening 54. A first part 210a of a first conductive pillar 210 and a second conductive pillar 220 are respectively formed in the first opening 52 and the second opening 54 by electroplating process, as shown in FIG. 6B. A first conductive link 240 is formed on the first surface 12 and is in contact with the first part 210a of the first conductive pillar 210.

As shown in FIG. 6C, the first device 10 is disposed on an adhesive layer 62 of a carrier 60, wherein the first surface 12 is in contact with the adhesive layer 62. Then, the device 10 is thinned to expose an end of the first conductive pillar 210.

As shown in FIG. 6D, the second device 20 is disposed on the first device 10. Then, FIG. 6E shows that forming a third opening 56 on the second surface 22 to expose a fourth opening 58 of a second conductive pad 24 in a similar way to FIGS. 6A-6B. A second part 292b of the first insulation layer 292 and a third insulation layer 296 are respectively formed on sidewalls of the third opening 56 and the fourth opening 58. After that, second part 210b and a third conductive pillar 230 are respectively formed in the third opening 56 and the fourth opening 58 by electroplating process. A second conductive link 250 is formed on the second surface 22 and is in contact with the second par 210b of the first conductive pillar 210 and the third conductive pillar 230. In an embodiment, the second conductive link 250 is the redistribution layer on the second device 20. It should be noted that the second part 210b of the first conductive pillar 210 is in contact with the third conductive pillar 230. At last, the carrier 60 is removed.

FIG. 6F shows that the second conductive link 250 may serve as an external conductive link after a bump 282 disposed thereon.

FIG. 7 shows a cross-sectional view of a conductive plug structure in accordance with another embodiment of the present invention. In this embodiment, a conductive plug structure 300 connected to a first device 10 that has a first surface 12 exposed and a second device 20 stacked on the first device 10 in a semiconductor device package. The first device 10 and the second device 20 may be light sensor(s), control circuit(s), any other semiconductor device, wafers or chips. In the other word, the conductive plug structure 200 could be applied to a wafer to wafer package or a chip scale package.

The conductive plug structure 300 comprises a first conductive pillar 310, a second conductive pillar 320, a conductive link 330, a first conductive pad 14, and a second conductive pad 24. The first conductive pad 14 and the second conductive pad 24 are respectively located in the first device 10 and the second device 20. The first conductive pillar 310 is disposed between the first surface 12 and the first conductive pad 14, and extends downwardly from a bottom surface of the first conductive pad 14 and ends at the bottom end of the second device 20. In one embodiment, a first end 312 of the first conductive pillar 310 is exposed on the first surface 12, a second end 314 of the first conductive pillar 310 is in contact with the first conductive pad 14. The second conductive pillar 320 is disposed between the first surface 12 and the second conductive pad 24, and extends downwardly from a bottom surface of the second conductive pad and ends at the bottom end of the second device. In another embodiment, a first end 322 of the second conductive pillar 320 is exposed on the first surface 12, and a second end 324 of the conductive pillar 320 is in contact with the second conductive pad 24. In one embodiment, the conductive link 330 is redistribution layers disposed on the first surface 12. The conductive link 330 is in contact with the first end 312 of the first conductive pillar 310 and the first end 322 of the second conductive pillar 320. As a result, the first conductive pad 14 and the second conductive pad 24 are electrically connected.

In other embodiment, to avoid the electrical connection between the first conductive pillar 310 and the first device 10, a first insulation layer 292 is further disposed between the sidewall of the first conductive pillar 310 and the first device 10. Also, a second insulation layer 394 is further disposed between the sidewall of the second conductive pillar 320 and the first device 10, the sidewall of the second conductive pillar 320 and the second device 20.

In addition, the locations of the first conductive pad 14 and the second conductive pad 24 can be varied. In an embodiment, the second conductive pad 24 of the disclosure may be formed on the second surface 22 of the second device 20, to serve as an external electrical connection.

Although the above embodiments disclose a conductive plug structure in a stacked structure of two devices. In an embodiment, the conductive plug structure can also be implemented in a stacked structure of three or more devices to connect two conductive pads.

FIG. 8 shows a cross-sectional view of a light sensor device in accordance with one embodiment of the present invention. The light sensor device package 400 is a backside illumination photosensitive device, comprising a carrier 410, and a light sensor 420. The carrier 410 has a surface 411 and a first surface 412. The light sensor 420 is disposed on the surface 411 and electrically connects to the carrier 410, wherein the light sensor 420 has a second surface 422 exposed. The light sensor 420 has a sensor array 426 and an interconnection 428, wherein the sensor array 426 electrically connects to the carrier 410 through the interconnection 428.

In this embodiment, the sensor array 426 includes a plurality of CMOS devices or charge couple devices, the carrier 410 may comprise controlling circuit or circuit with other functions. The sensor array may further comprise an optical film 427 and a color filter 429. Light passes through the optical film 427 and the color filter 429 is absorbed by the CMOS devices or charge couple devices, then the light is converted to electrical signals.

In another embodiment, the light sensor 420 may further comprise a transparent layer 421 which comprises the second surface 422 and an adhesive layer 423. The adhesive layer 423 is disposed on the sensor array 426, and the transparent layer 421 is disposed on the adhesive layer 423. The material of the transparent layer 421, for example, is polymethyl methacrylate, acrylic resin, or any other transparent materials.

FIG. 9 shows a cross-sectional view of a conductive plug structure in the light sensor device in FIG. 8, wherein the conductive plug structure 100 in FIG. 1 is implemented. The carrier 410 serves as the first device 10, the light sensor 420 serves as the second device 20, conductive pad 414 with an opening 414a serves as the first conductive pad 14, and conductive pad 424 serves as the second conductive pad 24. In a similar way to FIG. 1, the conductive pads 414 and 424 are electrically connected by the conductive plug structure 100.

FIG. 10 shows a cross-sectional view of the conductive plug structure of FIG. 1 implemented in a light sensor device in accordance with one embodiment of the present invention. The difference between this embodiment and the embodiment of FIG. 9 is that the conductive pad 424 is disposed on the second surface 422. The conductive plug structure 100 in this embodiment passes through the carrier 410 and the light sensor 420, so the conductive pad 424 serves as an external electrical connection by further disposing a bump thereon.

FIG. 11 shows a cross-sectional view of the conductive plug structure of FIG. 7 in a light sensor device in accordance with one embodiment of the present invention. The carrier 410 serves as the first device 10, the light sensor 420 serves as the second device 20, conductive pad 414 with serves as the first conductive pad 14, and conductive pad 424 serves as the second conductive pad 24. In a similar way to FIG. 7, the conductive pads 414 and 424 are electrically connected by the conductive plug structure 300. In another embodiment, the conductive link 330 is further in contact with a bump to serve as an external electrical connection for area array package. As a result, as the conductive plug structure 300 is formed, the redistribution layer for external electrical connection is also completed in the manufacturing process.

FIG. 12 shows a cross-sectional view of the conductive plug structure of FIG. 7 in a light sensor device in accordance with another embodiment of the present invention. The difference between the embodiment and the embodiment of FIG. 11 is that the conductive pad 424 is disposed on the second surface 422. The conductive plug structure 300 in the embodiment passes through the carrier 410 and the light sensor 420, so the conductive pad 424 serves as an external electrical connection by further disposing a bump thereon. In another embodiment, the conductive pad 424 may be connected to an external device, for example, an automatic focus system.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A conductive plug structure disposed in a first device and a second device stacked below the first device, the conductive plug structure comprising:
a first conductive pad disposed in the first device, the first conductive pad has an opening;
a first conductive pillar disposed above the first conductive pad, wherein a bottom end of the first conductive pillar is in contact with the first conductive pad and fully covers the opening;
a second conductive pad disposed at the second device; and
a second conductive pillar disposed between the first conductive pad and the second conductive pad, the second conductive pillar contacting and extending from the bottom end of the first conductive pillar, passing through the opening, and contacting the second conductive pad.

2. The conductive plug structure of claim 1, wherein the second conductive pad is disposed in the second device.

3. The conductive plug structure of claim 1, wherein the second conductive pad is disposed on a surface of the second device.

4. The conductive plug structure of claim 1, wherein the second conductive pillar is in contact with an inner sidewall of the first conductive pad that surrounds the opening.

5. The conductive plug structure of claim 1, further comprising an insulation layer surrounding a sidewall of the second conductive pillar and located below the first conductive pad.

6. A conductive plug structure disposed in a first device and a second device stacked below the first device, the conductive plug structure comprising:
a first conductive pad disposed in the first device;
a second conductive pad disposed in the second device;
a first conductive link disposed at the first device;
a second conductive link disposed at the second device;
a first conductive pillar passing through the first device and the second device;
a second conductive pillar extending from the first conductive pad and the first conductive link, wherein the second conductive pillar is in contact with the first conductive pad and the first conductive link; and
a third conductive pillar extending from the second conductive pad and the second conductive link, wherein the third conductive pillar is in contact with the second conductive pad and the second conductive link.

7. The conductive plug structure of claim 6, wherein the first conductive link is disposed on an exposed surface of the first device, and the second conductive link is disposed on an exposed surface of the second device.

8. The conductive plug structure of claim 6, further comprising a first insulation layer surrounding a sidewall of the first conductive pillar, and the first insulation layer passes through the first device and the second device.

9. The conductive plug structure of claim 6, further comprising a second insulation layer surrounding a sidewall of the second conductive pillar, and a third insulation layer surrounding a sidewall of the third conductive pillar.

10. A conductive plug structure disposed in a first device and a second device stacked below the first device, the conductive plug structure comprising:
a first conductive pad disposed at the first device;
a second conductive pad disposed in the second device;
a first conductive pillar extending from the first conductive pad to a bottom surface of the second device;
a second conductive pillar extending from the second conductive pad to the bottom surface of the second device; and
a conductive link disposed on the bottom surface of the second device, wherein the conductive link is in contact with the first conductive pillar and the second conductive pillar.

11. The conductive plug structure of claim 10, wherein the first conductive pad is disposed on an exposed surface of the first device.

12. The conductive plug structure of claim 10, further comprising a first insulation layer surrounding a sidewall of the first conductive pillar, and a second insulation layer surrounding a sidewall of the second conductive pillar.

13. A package structure of a light sensor device, comprising:
a carrier has a first surface, wherein a first conductive pad with an opening is disposed at the carrier;
a light sensor device disposed on the first surface, the light sensor device being electrically connected to the carrier, the light sensor device comprising:
a sensor array;
a patterned conductive layer disposed between the sensor array and the carrier;
a second conductive pad; and
a conductive plug structure disposed in the carrier and the light sensor, the conductive plug structure comprising:
a first conductive pillar disposed below the first conductive pad, wherein a top end of the first conductive pillar is in contact with the first conductive pad and fully covers the opening; and
a second conductive pillar disposed between the first conductive pad and the second conductive pad, the second conductive pillar contacting and extending from the top end of the first conductive pillar, passing through the opening, and contacting the second conductive pad.

14. The package structure of claim 13, wherein the second conductive pad is disposed on an exposed surface of the light sensor device.

15. The package structure claim 13, wherein the light sensor device further comprises:
a transparent layer disposed on the sensor array; and
a adhesive layer disposed between the transparent layer and the sensor array.

16. A package structure of a light sensor device, comprising:
a carrier has a first surface, wherein a first conductive pad with an opening is disposed at the carrier;
a light sensor device disposed on the first surface, the light sensor being electrically connected to the carrier, the light sensor device comprising:
a sensor array;
a patterned conductive layer disposed between the sensor array and the carrier;
a second conductive pad; and
a conductive plug structure disposed in the carrier and the light sensor, the conductive plug structure comprising:
a first conductive pillar contacting and extending from the first conductive pad to a bottom surface of the carrier;
a second conductive pillar contacting and extending from the second conductive pad to the bottom surface of the carrier; and
a patterned conductive layer disposed on the bottom surface of the carrier, wherein the patterned conductive layer is in contact with the first conductive pillar and the second conductive pillar.

17. The package structure of claim 16, wherein the second conductive pad is disposed on an exposed surface of the light sensor device.

18. The package structure of claim 16, wherein the light sensor device further comprises:
a transparent layer disposed on the sensor array; and
a adhesive layer disposed between the transparent layer and the sensor array.
